(19) United States
(12) Patent Application Publication
(10) Pub. No.: US 2003/0146445 A1
(43) Pub. Date: Aug. 7, 2003

(54) Electrode structure of LED and manufacturing of the same

(76) Inventor: Chang Hsiu Hen, HsinChu (TW)

Correspondence Address: Brian R. Coleman, Patent Attorney, Perkins Coie LLP, P.O. Box 2168, Menlo Park, CA, 95026-2168, US

(21) Appl. No.: 10/189,847

(22) Filed: Jul. 5, 2002

(30) Foreign Application Priority Data
Feb. 1, 2002 (TW) 091101833

(51) Int. Cl. H01L 33/00

(52) U.S. Cl. 257/93

(57) ABSTRACT

The present invention discloses an electrode structure of a light emitted diode and manufacturing method of the electrodes. After formed a pn-junction 2, 3 of a light emitted diode on a substrate 1, a layer of SiO₂ is deposited on the periphery of the LED die near the scribe line of the wafer, then a transparent conductive layer 5 is deposited, then a layer of gold or AuGe etc 6, is formed with an opening on the center of the die. After forming alloy with the semiconductor by heat treatment to form ohmic contact, a strip of aluminum (Al) 7 is formed on one side of the die on the front side for wire bonding and to be the positive electrode of the LED. The negative electrode 10 is formed on the substrate by metal contact. Another form of the electrode structure of the present invention is making both the positive electrode 7 and negative electrode 7a on the front side of the LED by etching the p-type semiconductor 3 of the pn-junction and forming a strip of negative electrode 7a on the n-type semiconductor area 2, the positive electrode is formed on the p-type semiconductor area.

### BACKGROUND OF THE INVENTION

1. Field of the Invention

The present invention relates to an electrode structure of semiconductor light emitted diodes (LED) and manufacturing method, and more particularly, to an electrode structure of LED suitable for overlap cascaded packaging.

2. Description of Relative Prior Art

Light emitted diode (LED) is a semiconductor light-emitting device, formed by a pn-junction, to transform electric power into a light source. LED has characteristics such as small volume, long life-time, low driving voltage, shock hardness, thermal stability, etc., suitable for applications which need to be thin and small, and used in traffic signals, back light source of LCD and other commercial products.

LED make use of variety of compound semiconductor such as □-□group materials,□-VI group materials, to form variety structures such as pn junction, double-hetero-junction(DH) and quantum well(QW), which can be used to design red, orange, yellow, green, blue, violet LEDs and also infrared, ultraviolet un-visible light LEDs. Materials suitable for making high intensity LED over 1000 mcd with wave length from long wave to short wave are AlGaAs, InGaAlP and InGaN, etc.

FIG. 1 shows a conventional LED structure. FIG. 1A is the top view, and FIG. 1B is the cross sectional view of AA′. On a substrate 1 (normally is n-type GaAs, GaP or GaN), n-type semiconductor 2 and p-type semiconductor 3 are epitaxied to form a pn-junction. A thin layer of gold (Au) or AuGe alloy 5a forms a round shaped ohmic contact on the center of the chip, then aluminum (Al) bonding pad 7 is deposited for wire bonding. A metal electrode 10 is deposited on the backside of the substrate as the negative electrode. Gold wire connects the positive electrode to the aluminum-bonding pad 7.

The electrode of a conventional LED on the center makes the electric field spreading uniformly around the chip, but gold and aluminum is opaqueness, light is blocking by the electrode too much if the electrode is large, but if too small, electric field would crowded in the center and the current density is increasing, this causes short life time of the LED, also in the center there will be a dark area which is obvious for near field observation; Also this electrode can not be use in overlap cascaded package. The overlap cascaded package is described in the U.S. Pat. No. 10/001,419 to Chang Hsiu Hen, names “Package structure of Full color LED formed by overlap cascaded Die bond”,

Another disadvantage of the convention electrode structure of a LED is that the lattice defect caused by cutting the chip along the scribe line. The electric field spreads from the electrode 7 via the p-type semiconductor to the substrate. Current will easily crowded at the lattice defect and forms light spots, which also hurt the junction and cause decreasing of lifetime. So it is needed to develop an electrode structure for LEDs to get longer lifetime, suitable for overlap cascaded packaging.

### SUMMARY OF THE INVENTION

The object of the present invention is to provide an electrode structure of light emitted diode with decreasing electric field intensity around the periphery of the chip and increasing the lifetime of the LED.

Another object of the present invention is to provide an electrode structure of light emitted diode with reflective metal around the chip to enhance the light emitting efficiency by reflecting the light emitted from the pn-junction to the reflective layer under the chip, and reflecting upward again. This makes the light emitted efficiently and there is no light emitted from the opaque region but only from the open window. If there is another LED with different color, overlap cascaded bonded on the chip, the two colors may mix to form a mixed color such as white light if the two colors are complementary. No light without mixed is emitted alone and form a noise.

Another object of the present invention is to provide an electrode structure of light emitted diode, using sapphire as the substrate, and the positive and negative electrodes are both on the front side. The transparent conductive layer on the backside of the substrate is used for die bonding only, and let the light comes from the bottom LED transmit upward to mix with the light of the upper LED to form a mixed light.

In order to achieve the above objects and improve the disadvantage of a conventional electrode structure of LED, two embodiments are presented. The electrode structure of LED of the present invention is suitable for overlap cascaded packaging. In a first prefer embodiment, the chip is used as the bottom chip of an overlap cascaded LED structure, where the substrate is the negative electrode. The substrate is non-transparent III-□compound semiconductor such as GaAs, GaP, GaN. A pn-junction or double hetero junction or quantum well is formed by epitaxy to be the junction of an LED. Silicon diode is formed on the periphery of each chip. After forming the electrode, the electrode, the oxide and the p-typed semiconductor around the chip will form a capacitance which will decrease the field strength near the scribe-line when positive voltage is applied to the LED, the lattice defect along the scribeline will not induce high current and will not form light spots, the lifetime of the LED will then increase. After the oxide is formed, a transparent conductive layer is then deposited on the p-type semiconductor and the oxide layer and formed ohmic contact with the p-type semiconductor. Reflective metal such as gold, gold-germanium (AuGe) or other gold alloy is formed on the transparent conductive layer. Finally, an open window is formed for light emitting. However, the area with reflecting metal will reflect the light emitted from the pn-junction back to the reflecting metal under the substrate and emitted again through the open window. This will increase the efficiency of the light source. The reflective metal layer and the transparent conductive layer should be thin such that there will no pilling during scribes the wafer into chips. The bonding pad is a strip of aluminum, aluminum alloy or gold which forms on one side of the chip for wire bonding, the thickness of the bonding pad is thicker then the transparent conductive layer and the reflective metal layer for wire bonding. A metal negative electrode is formed on the backside of the substrate to connect the negative electrode to a bonding seat or a pc board and to reflect the light upward.

In a second embodiment, the chip is used as the intermediate layer of an overlap cascaded LED structure. The substrate for epitaxy is a transparent sapphire (Al₂ O₃). Since sapphire is not conducting, so the negative electrode must be on the front side of the chip. A strip of p-type semiconductor on one side of the chip should be etched away and the n-type semiconductor is exposed, silicon dioxide is deposited and patterned on the n and p-type semiconductor so that the silicon dioxide is formed on the bonding pad area and the periphery of the chip. A transparent conductive layer is deposited on the n and p-type semiconductor and the oxide layer to form ohmic contact with the n-type semiconductor and p-type semiconductor. A reflective metal layer is formed over the p-type and n-type semiconductor. An open window is formed on the p-type semiconductor for light emitting. A negative bonding pad is formed on the n-type semiconductor area and a positive bonding pad is formed on one side of the p-type semiconductor area. A transparent conductive layer is deposited on the bottom of the substrate for bonding with the lower LED chip in overlap cascaded package structure. The transparent layer transmits the light from the lower LED to mix with light of the LED above it to form a different color light.

### BRIEF DESCRIPTION OF THE DRAWING

FIG. 1A (prior art) shows the top view of the electrode structure of an LED.

FIG. 1B (prior art) shows the cross section of the electrode structure of an LED along A-A′ of FIG. 1A.

FIG. 2 shows the electrode structure of an LED according to the first embodiment of the present invention.

FIG. 3 is the cross section along B-B′ of FIG. 2.

FIG. 4A, B, and C show the manufacturing steps of the electrode of an LED according to the first embodiment of the present invention.

FIG. 5 shows the cross sectional view of overlap cascaded packaging of another LED on the LED according to the first embodiment of the present invention.

FIG. 6 shows the top view of the electrode structure of an LED according to the second embodiment of the present invention.

FIG. 7 shows the cross section along C-C′ of FIG. 6

FIG. 8A, B, C and D show the manufacturing steps of the electrode of an LED according to the second embodiment of the present invention.

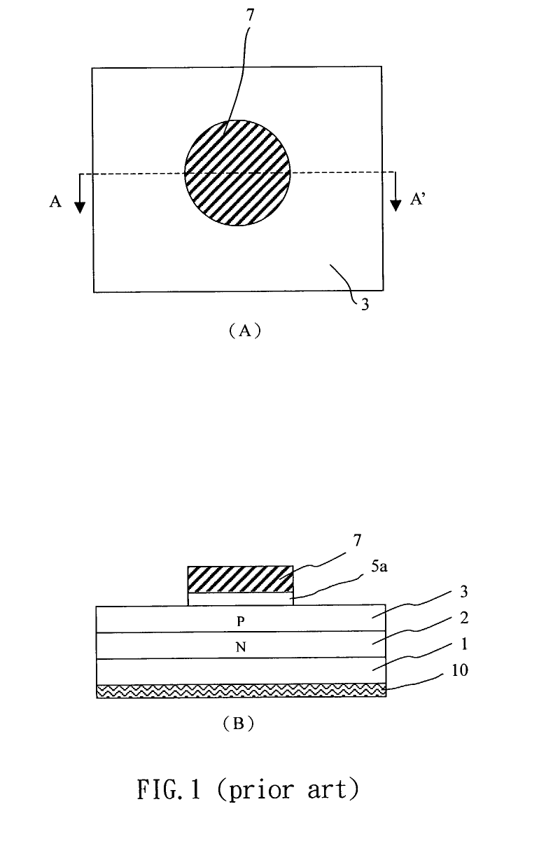

### DETAIL DESCRIPTION OF THE INVENTION

Referred embodiments of the present invention will be explained with refer to the accompanying drawings. The color, material and junction structure of the LED chip is not limited, any light emitted diode can use the electrode structure of the present invention. The electrode structure of the present invention is use in overlap cascaded structure packages of different color LED chips, by mixing two or three color light to have a different color light or white light.

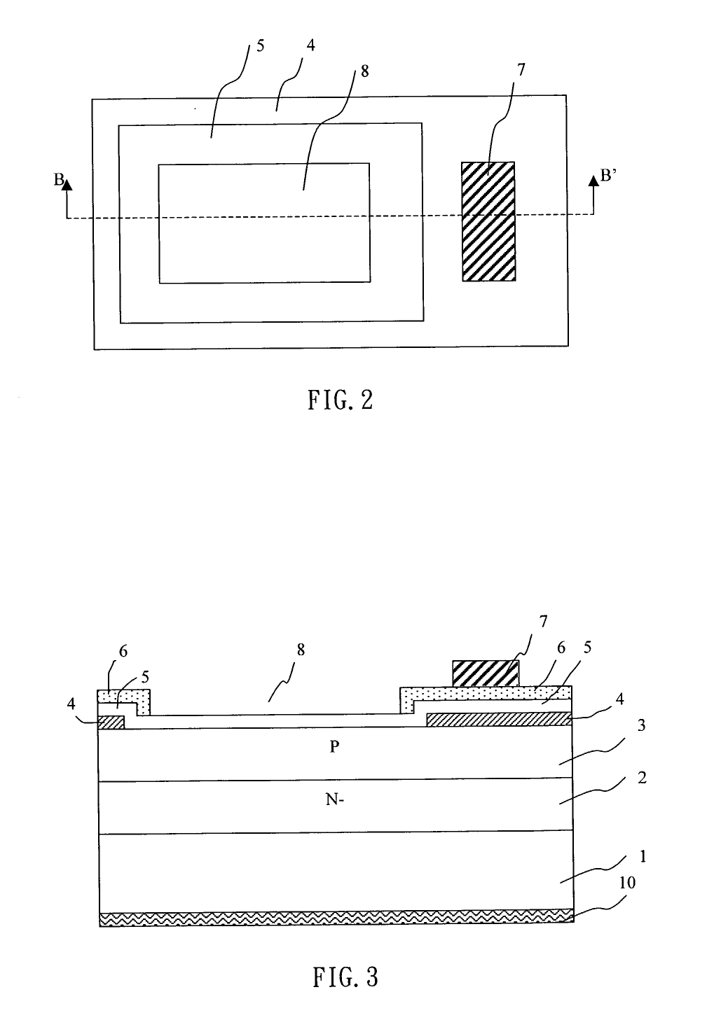

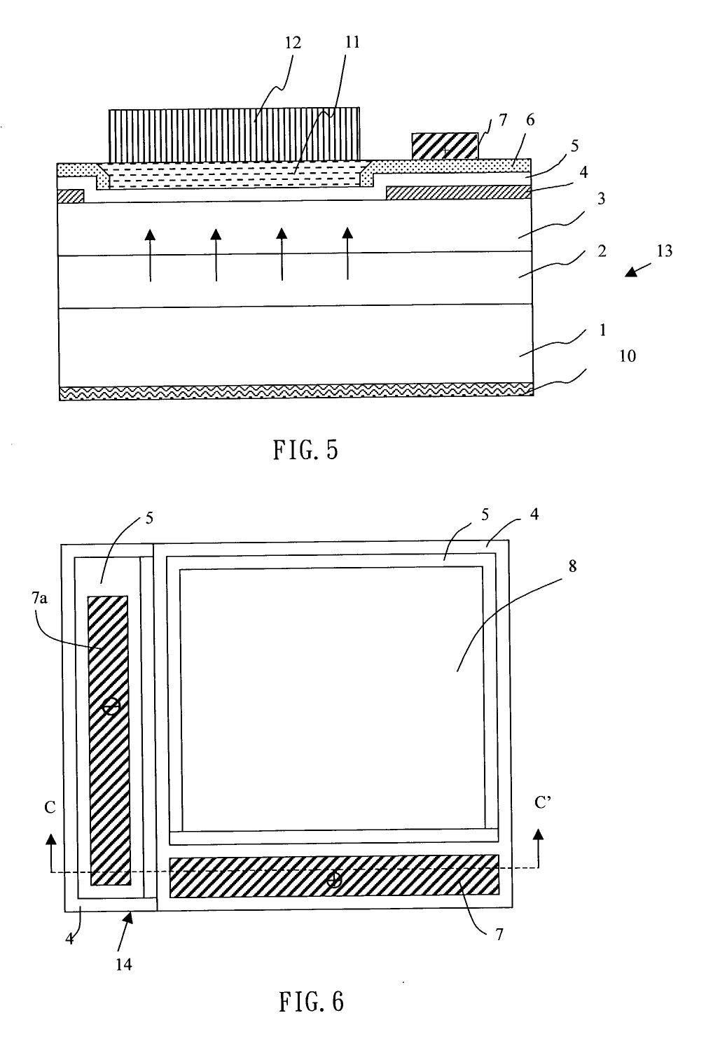

FIG. 2 shows the electrode structure of a bottom layer LED for overlap cascaded packaging of the first embodiment of the present invention. FIG. 3 is the cross section along BB′ of FIG. 2. Substrate 1 is always a non transparent □-□group or □-□ group compound semiconductor such as GaAs,GaP or GaN. A layer of n-type semiconductor 2 is formed by epitaxy technology on the substrate 1(see the cross sectional view of FIG. 3). Then a p-type semiconductor 3 is expitaxied to form a pn- junction as the light emitted diode. The pn- junction may be double hetero structure or quantum well structure. An electrode structure of the present invention is formed on the p-type semiconductor: First, a silicon dioxide layer 4 of 1000 Å to 10000 Å is deposited on the p-type semiconductor. By using a first mask in lithography and etching process to etch away the silicon dioxide to form an open window and keep the silicon dioxide around the chip and under the bonding pad 7. The width of oxide 4 is 5-20 μm around the chip, but under the positive bonding pad 7, the width of the oxide layer 4 is larger than the metal bonding pad 7, so that after the electrode is formed, the metal electrode 5, 6, the silicon dioxide layer 4 and the p-type semiconductor 3 will form a capacitor which will decrease the electric field intensity around the scribe line. Under this weaker electric field, the lattice defects caused by scribing will not extraordinary emit lights to form light spots, and the lifetime of the LED chip will increase. Next a transparent conductive layer 5 with thickness of 200 Å to 10000 Å, the better of 500 Å to 1000 Å, is deposited on the p-type semiconductor 3 and silicon dioxide 4 to form omhic contact with the p-type semiconductor 3. When a positive voltage is applied on the pn-junction via the bonding pad, the reflective metal layer 6 and the transparent conductive layer 5, light will emit through the open window of the reflective metal layer 6. The reflective metal layer 6 such as AuGe, Au or other gold alloys, with thickness of 200 Å to 5000 Å, the better of 500 Å, is deposited on the transparent conductive layer 5, with an open window 8 on the center for light emitting. But if there is a reflective metal layer 6, light is reflected back and upward again by the bottom reflective metal and emitted through the open window, which will increase the light efficiency. If there is another LED 12 in overlap cascaded packaging on it, (ref to FIG. 5 for cascaded structure), all the light via the open window emitted to another LED 12 will mix with the light of LED 12. But around the periphery no light from the bottom LED is emitted without mixing with the light from LED 12, and noise may eliminate. The thickness of the reflective metal layer 6 and the transparent conductive layer 5 is thin, so that avoid pilling when scribing into chips. Finally bonding pad 7 is deposited on the reflective metal 6 and formed on one side of the chip (the right side of FIG. 2 and FIG. 3) The bonding pad 7 is a strip of Al, aluminum alloy, Au, or, gold alloys with thickness of 1000 Å to 20000 Å, the better of 5000 Å, which is thicker than the transparent conductive layer 5 and the reflective metal layer 6, for aluminum wire or gold wire boding. A metal negative electrode 10 is formed on the bottom of the substrate to be the negative electrode, which can be bonded to a PC board or a bonding seat, also to be the reflective layer to reflect lights upward.

The electrode structure as described above with electrode 7 on one side of the chip, around the chip there is a reflecting metal layer 6 to reflect the light except the open window 8, the light can emit from the open window 8 through the transparent conductive layer 5, thus the conversion efficiency of light will increase, and there will be no light without mixing coming out as a noise. Also the silicon dioxide 4 around the chip and under the bonding pad 7 will decrease the electric field intensity along the scribe line, so that the lattice defect induced by scribing will not extraordinary emit lights to form light spots, and the lifetime of the LED chip will increase. The oxide under the bonding pad 7 forms a soft seat to absorb the stress of wire bonding without hurting the pn-junction and forming defects under the bonding pad 7.

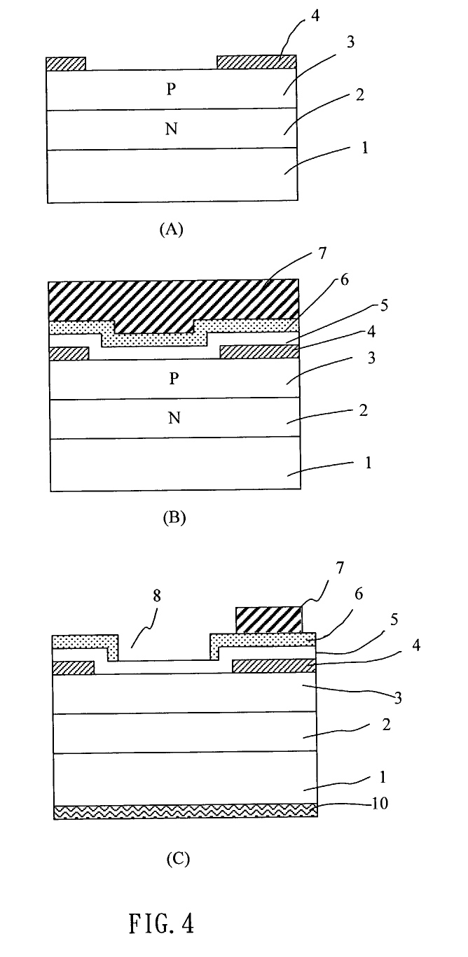

FIG. 4 shows the manufactory steps of the electrode of LED of the first embodiment of the present invention. As shown in FIG. 4A, n-type semiconductor 2 and p-type semiconductor 3 are epitaxied on substrate 1 to form a pn-junction, silicon dioxide layer 4 with thickness of 1000 Å to 10000 Å is deposited on the p-type semiconductor 3, lithography and etching step is performed with a first mask to remove the oxide layer 4 except that around the chip and that under the bonding pad 7, The width of the oxide 4 is 5-20 μm around the chip, but under the positive bonding pad 7, the width of the oxide layer 4 is larger than the bonding pad 7 to release the stress of wire bonding. Then as in FIG. 4B, a transparent conductive layer 5 with thickness of 200 Å to 10000 Å, the better of 500 Å to 1000 Å is deposited, next a reflective metal layer 6 of AuGe, Au or other gold alloy with thickness of 200 Å to 5000 Å, the better of 500 Å is deposited, next a layer of Al or aluminum alloy is deposited to form the bonding pad 7. Then as in FIG. 4C, by using a second mask, lithography and etching process steps to form the bond pad 7. Then using a third mask, lithography and etch process steps to form the open window 8 on the reflecting conductive layer 6. Finally, metal such as Al. aluminum alloy or gold is deposited on the bottom of the substrate to form a negative electrode 10.

FIG. 5 shows the cross sectional view of the overlap cascaded packaging with another LED 12 on the LED 13 according to the first embodiment of the present invention. The electrodes of the front side and the backside of LED 12 are formed by transparent conductive layers, and bonding pads are form on the corners of the chip. The size of the chip is the same as the open window 8. LED 12 is attached by transparent epoxy to the LED of the first embodiment of the present invention. So that two different color light can mix to form a light of other color.

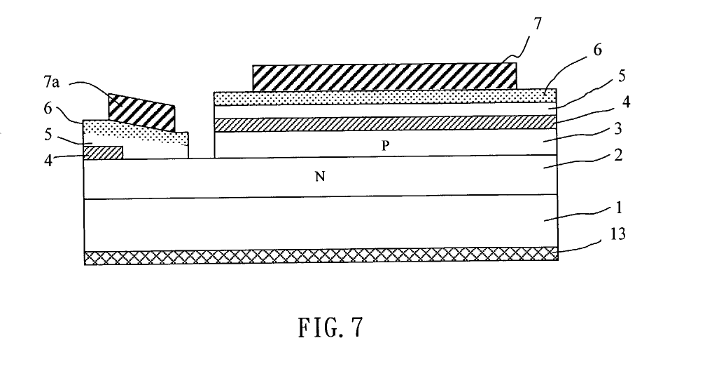

FIG. 6 shows the top view of the electrode structure of LED according to a second embodiment of the present invention. FIG. 7 is the cross section along C-C′ of FIG. 6. The chip of this embodiment is used as the intermediate die of the overlap cascaded packaging. Sapphire is used as the epitaxy substrate 1 for transparent of light. Since sapphire is not conducting and wire bond is not possible if the negative electrode is on the bottom of the substrate, so the negative electrode must be put on the front side of the chip. First an n-type semiconductor 2 and a p-type semiconductor 3 is epitaxied on the sapphire 1 to form the active pn-junction of the LED (see the cross section of FIG. 7). On one side of the chip, a strip of p-type semiconductor is etched away by lithography and etching, the n-type semiconductor 2 is then exposed. A silicon dioxide layer 4 is deposited and patterned on the periphery of the chip, the positive bonding pad 7 and negative bonding pad 7a areas. This may decrease the electric field strength near the scribe line and increase the lifetime of the LED, also form a soft layer to absorb the stress of wire bonding to avoid forming lattice defect in the pn-junction under the bonding pad. Next a transparent conductive layer 5 is deposited on the p-type and n-type semiconductor, also on the oxide layer 4, to form ohmic contact with the semiconductor. Then a reflective metal layer 6 is deposited and formed an open window 8 on the p-type semiconductor area 3. Finally a positive bonding pad 7 is formed on the p-type semiconductor 3 and a negative bonding pad 7a is formed on the n-type semiconductor area. The thickness of the films is the same as that in the first embodiment, and is not discuss any more here.

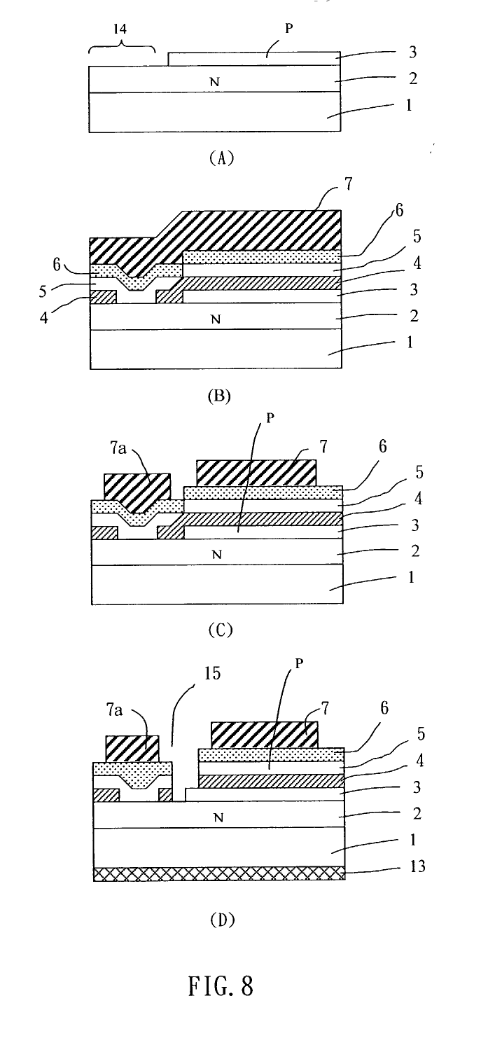

FIG. 8A, 8b, 8C and 8D are the manufacturing steps of the electrodes of a LED according to the second embodiment of the present invention. As shown in FIG. 8A, n-type semiconductor 2 and p-type semiconductor 3 are epitaxied on a sapphire substrate 1, then etch away a strip of p-type semiconductor by lithography and etching to form a step 14 with width of 100-200 μm, the n-type semiconductor 2 under the step 14 is then exposed. As in FIG. 8B, a silicon dioxide of thickness 1000 Å to 1000 Å is deposited, a first mask is used to pattern the silicon dioxide, remove the oxide on the contact area and keep the oxide 4 around the periphery of the chip and under the positive bonding pad 7. The width of the oxide 4 is 5-20 μm except that under the positive bonding pad. Under the positive bonding pad 7 the oxide 4 is wider than the positive bonding pad 7 for absorbing the stress of wire bonding. Under the negative bonding pad, the oxide 4 is removed except around the periphery of the chip and around the p-type semiconductor, as shown in FIG. 8B. Then a transparent conductive layer 5 with thickness of 200-10000 Å, the better of 500-1000 Å is deposited. Next a reflective metal layer 6 of AuGe, Au or silicon gold alloy with thickness of 200 Å to 5000 Å, the better of 500 Å is deposited. Finally a layer of Al, aluminum alloy, gold or gold alloy is deposited to form the bonding pad 7, as shown in FIG. 8C. A second mask is used to perform lithography and etching to form the positive bonding pad 7 and the negative bond pad 7a. Then a third mask is used to perform lithography and etching, to form a spacing trench 15 between the n-type semiconductor and the p-type semiconductor for isolation. Finally a transparent conductive layer 13 with thickness of 200 Å to 10000 Å, the better of 500 Å to 2000 Å is deposited on the backside of the substrate for overlap cascaded die bond.

The embodiments mentioned above are only examples for explaining the present invention. Any similar products modified according to this disclosure should be regarded within the scope of the present invention.

What is claimed is:

1. An electrode structure of light emitted diode, comprising:
a substrate formed by GaAs, GaP, used as epitaxial substrate;
a pn-junction of light emitted diode, epitaxied on said substrate;
a silicon dioxide film is formed around the chip to decrease the electric field near the scribe line;
a transparent conductive layer formed on said p-type semiconductor and said silicon dioxide layer such that positive voltage is applied to the p-type semiconductor uniformly;
a reflective metal layer of gold germanium or gold alloy, deposited on said transparent conductive layer, and formed an open window on the center such that light can emit form said window;
a bonding pad formed by aluminum, aluminum alloy or gold, is a strip formed on one side of the chip to be the positive bonding pad;
a metal electrode formed on the bottom of said substrate to be a reflecting layer of light and a negative electrode, which may bond to a pc board or bonding seat of a package structure.

2. The electrode structure of light emitted diode according to claim 1, where in the width of said silicon dioxide is at least 5-20 μm, and the thickness is 1000 Å to 10000 Å.

3. The electrode structure of light emitted diode according to claim 1, wherein the thickness of said transparent conductive layer is 200 Å to 10000 Å, the better of 500 Å to 1000 Å.

4. The electrode structure of light emitted diode according to claim 1, wherein the thickness of the reflective metal layer is 200 Å to 5000 Å, the better is 500 Å, and the edge of said open window of said reflective metal layer to the edge of said chip is more than 10 μm.

5. The electrode structure of light emitted diode according to claim 1, wherein the thickness of said bonding pad is 1000 Å to 20000 Å, the better is 5000 Å; and the width of said bonding pad is 50 μm to 200 μm, the better is 100 μm; and the edge of said bonding pad keeps a distance from said scribe line more than 20 μm.

6. An electrode structure of light emitted diode, comprising:
a substrate formed by sapphire, used as epitaxial substrate;
a pn-junction of light emitted diode, epitaxied on said substrate; on one side of the chip, a strip of the p-type semiconductor is removed;
a silicon dioxide film, formed around the chip of the n-type and p-type semiconductor to decrease the electric field near the scribe line;
a transparent conductive layer, formed on said n-type and p-type semiconductor and silicon dioxide layer such that positive voltage is applied on said p-type semiconductor and negative voltage is applied on said n-type semiconductor uniformly;
a reflective metal layer of gold germanium or gold alloy, deposited on said transparent conductive layer, and formed an open window on the center of said p-type semiconductor such that light can emit from said open window;
a bonding pad formed by aluminum, aluminum alloy or gold, formed on one side of the p-type and n-type semiconductor in the form of two strips to be the positive and negative boding pads;
a transparent metal layer formed on the bottom of said substrate to transmit the light from a bottom layer LED to mix with the light from an upper layer LED to form another color of light, also used as a die bonding layer for overlap cascaded packaging.

7. The electrode structure of light emitted diode according to claim 2, where in the width of said silicon dioxide is at least 5-20 μm, and the thickness is 1000 Å to 10000 Å.

8. The electrode structure of light emitted diode according to claim 2, wherein the thickness of said transparent conductive layer is 200 Å to 10000 Å, the better of 500 Å to 10000 Å.

9. The electrode structure of light emitted diode according to claim 2, wherein the thickness of the reflective metal layer is 200 Å to 5000 Å, the better is 500 Å, and the edge of said open window of said reflective metal layer to the edge of said chip is more than 10 μm.

10. The electrode structure of light emitted diode according to claim 2, wherein the thickness of said bonding pad is 1000 Å to 20000 Å, the better is 5000 Å; and the width of said bonding pad is 50 μm to 200 μm, the better is 100 μm; and the edge of said bonding pad keep a distance from said scribe line more than 20 μm.

11. The electrode structure of light emitted diode according to claim 1, wherein the width of the p-type semiconductor removed is 100 μm to 150 μm.

12. The electrode structure of light emitted diode according to claim 2, wherein the thickness of said transparent conductive layer on the bottom of said substrate is 200 Å to 10000 Å, the better is 500 Å to 10000 Å.

13. A manufacturing method of light emitted diode, includes the following steps:
(a) Epitaxying an n-type and p-type semiconductor on a substrate to form a pn-junction;
(b) Depositing a silicon dioxide layer, using a first mask to perform lithograph and etching to form a layer of silicon dioxide around the chip near the scribe line and under the bonding pad to be formed;
(c) Depositing a transparent conductive layer to form an ohmic and transparent contact;
(d) Depositing a layer of gold, gold germanium or gold silicon alloy to form a reflective layer;
(e) Depositing a layer of aluminum, aluminum alloy or gold to form positive bonding pad;
(f) Using a second mask to perform lithography and etching to form positive bonding pad;
(g) Using a third mask to perform lithography and etching to form an open window on the reflective metal layer;

14. A manufacturing method of light emitted diode, includes the following steps:
(a) Epitaxying an n-type and a p-type semiconductor on substrate of transparent sapphire to form a pn-junction;
(b) Removing a strip of said p-type semiconductor by lithography and etching by using a first mask to expose said n-type semiconductor to be the negative electrode area;
(c) Depositing a silicon dioxide layer, using a second mask to perform lithography and etching to form a layer of silicon dioxide around the chip near the scribe line and under the positive and negative bonding pads;
(d) Depositing a transparent conductive layer to form ohmic and transparent contact;
(e) Depositing a layer of gold, gold germanium or gold silicon alloy to form a reflective metal layer;
(f) Depositing a layer of aluminum, aluminum alloy or gold to form positive and negative bonding pads;
(g) Using a third mask to perform lithography and etching to form said positive and negative bonding pads;
(h) Using a fourth mask to perform lithography and etching to form an open window on said reflective metal layer on said p-type semiconductor area for light emitting, and form a trench between the n-type and p-type semiconductor to isolate the positive and negative electrode.

15. The manufacturing method of light emitted diode according to claim 9, where in the width of said silicon dioxide is at least 5-20 μm, and the thickness is 1000 Å to 10000 Å.

16. The manufacturing method of light emitted diode according to claim 9, wherein the thickness of said transparent conductive layer is 200 Å to 10000 Å, the better of 500 Å to 1000 Å.

17. The manufacturing method of light emitted diode according to claim 9, wherein the thickness of the reflective metal layer is 200 Å to 5000 Å, the better is 500 Å, and the edge of said open window of said reflective metal layer to the edge of said chip is more than 10 μm.

18. The manufacturing method of light emitted diode according to claim 9, wherein the thickness of said bonding pad is 1000 Å to 20000 Å, the better is 5000 Å; and the width of said bonding pad is 50 μm to 200 μm, the better is 100 μm; and the edge of said bonding pad keep a distance from said scribe line more than 20 μm.

19. The manufacturing method of light emitted diode according to claim 9, wherein the width of the p-type semiconductor removed is 100 μm to 150 μm.

20. The manufacturing method of light emitted diode according to claim 10, wherein the thickness of said transparent conductive layer on the bottom of said substrate is 200 Å to 10000 Å, the better is 500 Å to 2000 Å.

21. The manufacturing method of light emitted diode according to claim 10, where in the width of said silicon dioxide is at least 5-20 μm, and the thickness is 1000 Å to 10000 Å.

22. The manufacturing method of light emitted diode according to claim 10, wherein the thickness of said transparent conductive layer is 200 Å to 10000 Å, the better of 500 Å to 1000 Å.

23. The manufacturing method of light emitted diode according to claim 10, wherein the thickness of the reflective metal layer is 200 Å to 5000 Å, the better is 500 Å, and the edge of said open window of said reflective metal layer to the edge of said chip is more than 10 μm.

24. The manufacturing method of light emitted diode according to claim 10, wherein the thickness of said bonding pad is 1000 Å to 20000 Å, the better is 5000 Å; and the width of said bonding pad is 50 μm to 200 μm, the better is 100 μm; and the edge of said bonding pad keep a distance from said scribe line more than 20 μm.
